(19) United States
(12) Patent Application Publication
(10) Pub. No.: US 2024/0330543 A1
(43) Pub. Date: Oct. 3, 2024

(54) MODEL FOR CONSTRAINING RATE OFPENETRATION THROUGH LOADING RATE ANDDRILLSTRING VIBRATIONS ANALYSIS

(71) Applicant: SAUDI ARABIAN OIL COMPANY, Dhahran (SA)

(72) Inventor: Hussain Albahrani, Qatif (SA)

(73) Assignee: SAUDI ARABIAN OIL COMPANY, Dhahran (SA)

(21) Appl. No.: 18/191,229

(22) Filed: Mar. 28, 2023

(51) Int. Cl. G06F 30/23; E21B 41/00

(52) U.S. Cl. CPC G06F 30/23; E21B 41/00; E21B 2200/20

(57) ABSTRACT

Systems and methods for constraining rate of penetration through a loading rate and drillstring vibrations analysis are disclosed. The methods include obtaining a rock type of a formation to be drilled, determining a rock-type specific loading rate model for the rock type, obtaining surface drilling parameters for each of a plurality of rate of penetration (ROP) values; and obtaining a plurality of bottom hole assembly (BHA) designs. The methods further include determining impact forces for each of the plurality of BHA designs using a drill string vibrational model and the surface drilling parameters, predicting rock failure using the impact forces, rock type specific loading rate model, and a finite element model (FEM), and selecting particular surface drilling parameters based on the predicted rock failure.

### BACKGROUND

Every year the petroleum industry spends more than $6 billion in mitigating borehole instability issues that account for nearly half of the drilling-related nonproductive time. The causes of borehole instability may be classified into two broad categories: 1) the physio-chemical interactions between the borehole rock formation (especially shales) and the drilling fluid, and 2) mechanical factors, such as drill string vibrations impacting the borehole wall. Researchers believe borehole instability problems occur primarily due to the first category and neglect the impact of the second category, namely vibrations, on borehole instability.

In examining mechanical factors, it is observed that boreholes with instability issues tend to have a higher rate of penetration (ROP), which is proportional to the loading rate. Furthermore, the vibration of the drillstring in a borehole is known to damage rock formations in the borehole wall. Thus, understanding the interaction between drillstring vibrations and loading rate is necessary to understand, predict, and mitigate borehole instability. Accordingly, there exists a need for a system and methods to assess the impact of mechanical factors on borehole instability.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments disclosed herein relate to methods for constraining rate of penetration through a loading rate and drillstring vibrations analysis, including: obtaining a rock type of a formation to be drilled; determining a rock-type specific loading rate model for the rock type; obtaining surface drilling parameters for each of a plurality of rate of penetration (ROP) values; obtaining a plurality of bottom hole assembly (BHA) designs; determining impact forces for each of the plurality of BHA designs using a drill string vibrational model and the surface drilling parameters; predicting rock failure using the impact forces, rock type specific loading rate model, and a finite element model (FEM); and selecting particular surface drilling parameters based on the predicted rock failure.

In some aspects, the techniques described herein relate to a non-transitory computer-readable memory including computer-executable instructions stored thereon that, when executed on a processor, cause the processor to perform steps including: obtaining a rock type of a formation to be drilled; determining a rock-type specific loading rate model for the rock type; obtaining surface drilling parameters for each of a plurality of rate of penetration (ROP) values; obtaining a plurality of bottom hole assembly (BHA) designs; determining impact forces for each of the plurality of BHA designs using a drill string vibrational model and the surface drilling parameters; predicting rock failure using the impact forces, rock type specific loading rate model, and a finite element model (FEM); and selecting particular surface drilling parameters based on the predicted rock failure.

Other aspects and advantages of the claimed subject matter will be apparent from the following description and the appended claims.

### BRIEF DESCRIPTION OF DRAWINGS

FIG. 1 shows a drilling system in accordance with one or more embodiments.

FIG. 2 shows stress versus strain for a rock sample at different loading rates in accordance with one or more embodiments.

FIG. 3 shows tensile strength of rock as a function of loading rate for two hypothetical rock samples in accordance with one or more embodiments.

FIG. 4A shows three motions of a BHA in a borehole in accordance with one or more embodiments

FIG. 4B shows borehole impact patterns caused by lateral BHA motion in accordance with one or more embodiments.

FIG. 5 shows the discretization of the subsurface in the FEM along the axis of the borehole in accordance with one or more embodiments.

FIG. 6 shows the structure and organization of the FEM in accordance with one or more embodiments.

FIG. 7 shows a range between minimum and maximum mud weight required to avoid borehole instability for two borehole designs in accordance with one or more embodiments.

FIG. 8 shows the workflow of the geomechanical modeling tool in accordance with one or more embodiments.

FIG. 9 presents a flowchart of a method in accordance with one or more embodiments.

FIG. 10 depicts a block diagram of a computer system used to provide computational functionalities associated with described algorithms, methods, functions, processes, flows, and procedures as described in this disclosure in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

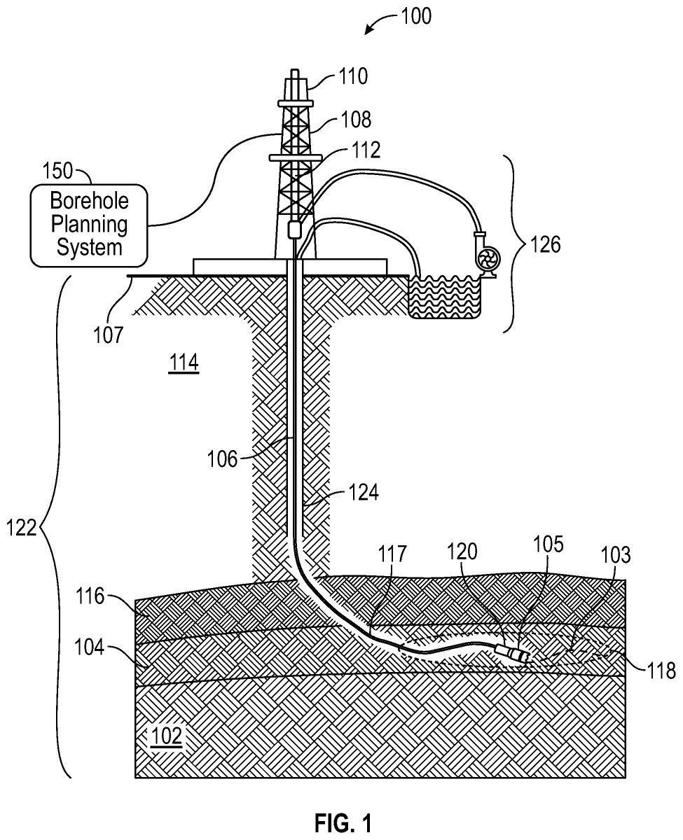

In the following description of FIGS. 1-10, any component described regarding a figure, in various embodiments disclosed herein, may be equivalent to one or more like-named components described with regard to any other figure. For brevity, descriptions of these components will not be repeated regarding each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “a borehole” includes reference to one or more of such boreholes.

Terms such as “approximately,” “substantially,” etc., mean that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

It is to be understood that one or more of the steps shown in the flowcharts may be omitted, repeated, and/or performed in a different order than the order shown. Accordingly, the scope disclosed herein should not be considered limited to the specific arrangement of steps shown in the flowcharts.

Although multiple dependent claims may not be introduced, it would be apparent to one of ordinary skill that the subject matter of the dependent claims directed to one or more embodiments may be combined with other dependent claims.

In one aspect, embodiments disclosed herein relate to three integrated models that predict mechanical rock failure at a borehole wall. The first integrated model is a model that, for a particular rock type, determines the stress-strain path for each ROP under consideration. The second integrated model considers a bottomhole assembly (BHA) design and its corresponding vibrational model. This model determines if a particular ROP value leads to resonance frequencies. If it does, the second integrated model assesses the impact force that is exerted by the BHA on the borehole wall. The third integrated model is a finite element model (FEM) that takes both the output of the rock-type specific loading rate model (the first integrated model) and the output from the drill string vibrational model (the second integrated model) and uses them to predict geomechanical forces and determine if they cause rock failure in the borehole.

The combination of the three integrated models will be referred to as the geomechanical modeling tool. As output, the geomechanical modeling tool will determine a range of drilling parameters that minimize the likelihood of borehole instability while maximizing the ROP for specific drill string configurations and rock formations. When adequately modelled, calibrated, and verified, the use of the geomechanical modeling tool may result in appreciable cost savings and reduced risk to equipment, the borehole, and the human workforce. This, in turn, will increase productivity and improve well design workflows and risk mitigation strategies.

Apart from the three integrated models, another step is required for implementation of the method: For an ROP value under consideration, a drilling operator must determine, through existing techniques, the surface drilling parameters (weight on bit (WOB), revolution per minute (RPM), and torque) that lead to a particular ROP value under consideration.

FIG. 1 shows a drilling system (100) in accordance with one or more embodiments. Although the drilling system (100) shown in FIG. 1 is used to drill a borehole on land, the drilling system (100) may also be a marine borehole drilling system. The example of the drilling system (100) shown in FIG. 1 is not meant to limit the present disclosure.

As shown in FIG. 1, a borehole path (103) may be drilled by a drill bit (105) attached by a drillstring (106) to a drill rig located on the surface (107) of the earth. The drill rig may include framework, such as a derrick (108), to hold drilling machinery. The top drive (110) sits at the top of the derrick (108) and provides torque, typically a clockwise torque, via the drive shaft (112) to the drillstring (106) in order to drill the borehole (117). The borehole (117) may traverse a plurality of overburden (114) layers and one or more cap-rock (116) layers to a hydrocarbon reservoir (104) within the subterranean region of interest (102). In accordance with one or more embodiments, the extended bandwidth seismic dataset may be used to plan a borehole (117) including a borehole path (103) and drill a borehole (117) guided by the borehole path (103). The borehole path (103) may be a curved borehole path, or a straight borehole path. All or part of the borehole path (103) may be vertical, and some borehole paths (103) may be deviated or have horizontal sections.

Prior to the commencement of drilling, a borehole plan may be generated. The borehole plan may include a starting surface location of the borehole (117), or a subsurface location within an existing borehole (117), from which the borehole (117) may be drilled. Further, the borehole plan may include a terminal location that may intersect with the target zone (118), e.g., a targeted hydrocarbon-bearing formation, and a planned borehole path (103) from the starting location to the terminal location. In other words, the borehole path (103) may intersect a previously located hydrocarbon reservoir (104).

Typically, the borehole plan is generated based on best available information at the time of planning from a geophysical model, geomechanical models encapsulating subterranean stress conditions, the trajectory of any existing boreholes (117) (which one may desire to avoid), and the existence of other drilling hazards, such as shallow gas pockets, over-pressure zones, and active fault planes. In accordance with one or more embodiments, the borehole plan is informed by an extended bandwidth seismic dataset acquired through a seismic survey conducted over the subterranean region of interest (102).

The borehole plan may include borehole geometry information such as borehole diameter and inclination angle. If casing (124) is used, the borehole plan may include casing type or casing depths. Furthermore, the borehole plan may consider other engineering constraints such as the maximum borehole curvature (“dog-log”) that the drillstring (106) may tolerate and the maximum torque and drag values that the drilling system (100) may tolerate.

A borehole planning system (150) may be used to generate the borehole plan. The borehole planning system (150) may comprise one or more computer processors in communication with computer memory containing the geophysical and geomechanical models, the extended bandwidth seismic dataset, information relating to drilling hazards, and the constraints imposed by the limitations of the drillstring (106) and the drilling system (100). The borehole planning system (150) may further include dedicated software to determine the planned borehole path (103) and associated drilling parameters, such as the planned borehole diameter, the location of planned changes of the borehole diameter, the planned depths at which casing (124) will be inserted to support the borehole (117) and to prevent formation fluids entering the borehole (117), and the drilling mud weights (densities) and types that may be used during drilling the borehole (117).

A borehole (117) may be drilled using a drill rig that may be situated on a land drill site, an offshore platform, such as a jack-up rig, a semi-submersible, or a drill ship. The drill rig may be equipped with a hoisting system, such as a derrick (108), which can raise or lower the drillstring (106) and other tools required to drill the well. The drillstring (106) may include one or more drill pipes connected to form a conduit and a bottom hole assembly (BHA) (120) disposed at the distal end of the drillstring (106). The BHA (120) may include a drill bit (105) to cut into subsurface (122) rock. The BHA (120) may further include measurement tools, such as a measurement-while-drilling (MWD) tool and logging-while-drilling (LWD) tool. MWD tools may include sensors and hardware to measure downhole drilling parameters, such as the azimuth and inclination of the drill bit (105), the WOB, and the torque. The LWD measurements may include sensors, such as resistivity, gamma ray, and neutron density sensors, to characterize the rock formation surrounding the borehole (117). Both MWD and LWD measurements may be transmitted to the surface (107) using any suitable telemetry system, such as mud-pulse or wired-drill pipe, known in the art.

To start drilling, or “spudding in” the well, the hoisting system lowers the drillstring (106) suspended from the derrick (108) towards the planned surface location of the borehole (117). An engine, such as a diesel engine, may be used to supply power to the top drive (110) to rotate the drillstring (106). The weight of the drillstring (106) combined with the rotational motion enables the drill bit (105) to drill the borehole (117).

The near surface is typically made up of loose or soft sediment or rock, so large diameter casing (124), e.g., “base pipe” or “conductor casing,” is often put in place while drilling to stabilize and isolate the borehole (117). At the top of the base pipe is the wellhead, which serves to provide pressure control through a series of spools, valves, or adapters. Once near-surface drilling has begun, water or drill fluid may be used to force the base pipe into place using a pumping system until the wellhead is situated just above the surface (107) of the earth.

Drilling may continue without any casing (124) once deeper, or more compact rock is reached. While drilling, a drilling mud system (126) may pump drilling mud from a mud tank on the surface (107) through the drill pipe. Drilling mud serves various purposes, including pressure equalization, removal of rock cuttings, and drill bit cooling and lubrication.

At planned depth intervals, drilling may be paused and the drillstring (106) withdrawn from the borehole (117). Sections of casing (124) may be connected and inserted and cemented into the borehole (117). Casing string may be cemented in place by pumping cement and mud, separated by a “cementing plug,” from the surface (107) through the drill pipe. The cementing plug and drilling mud force the cement through the drill pipe and into the annular space between the casing (124) and the borehole wall. Once the cement cures, drilling may recommence. The drilling process is often performed in several stages. Therefore, the drilling and casing cycle may be repeated more than once, depending on the depth of the borehole (117) and the pressure on the borehole walls from surrounding rock.

Due to the high pressures experienced by deep boreholes (117), a blowout preventer (BOP) may be installed at the wellhead to protect the rig and environment from unplanned oil or gas releases. As the borehole (117) becomes deeper, both successively smaller drill bits (105) and casing string may be used. Drilling deviated or horizontal boreholes (117) may require specialized drill bits or drill assemblies.

A drilling system (100) may be disposed at and communicate with other systems in the well environment. The drilling system (100) may control at least a portion of a drilling operation by providing controls to various components of the drilling operation. In one or more embodiments, the system may receive data from one or more sensors arranged to measure controllable parameters of the drilling operation. As a non-limiting example, sensors may be arranged to measure WOB, drill RPM, flow rate of the mud pumps (GPM), and ROP of the drilling operation. Each sensor may be positioned or configured to measure a desired physical stimulus. Drilling may be considered complete when a target zone (118) is reached, or the presence of hydrocarbons is established.

In one or more embodiments, the loading rate on a drillstring (106) is the rate at which a certain magnitude of load (i.e., stress) is applied to a solid body (such as a rock sample, as in this case). For example, if the target is to apply 1000 psi of load on the rock sample, the piston applying the load can reach this target magnitude within 5 seconds, in which case the loading rate is specified as 200 psi/s (which can also be expressed in GPa/s). Alternatively, since loading is applied by moving or lowering a piston against the sample, the loading rate may also be specified by the velocity of the piston (distance per time). In this case, the distance is the space between the piston and the sample. The ROP of the drill bit (105) during the drilling process is effectively applying a load to the borehole rock at a known rate. This connection between ROP and loading rate determines the deformation (strain) behavior of drilled rocks. As such, ROP and loading rate are used as interchangeable terms.

Higher loading rate subjects the rock formations at the bottom and to the sides of the borehole (117) to higher stresses. Thus, the relationship between loading rate and rock failure is complex and must be accurately modeled in order to determine the probability of geomechanical failure of the formations in the borehole wall. The expected rock failure limits are a function of the stresses caused by BHA vibrations, the rock type of the formations in the borehole (117), as well as the borehole environment (e.g., downhole pressure).

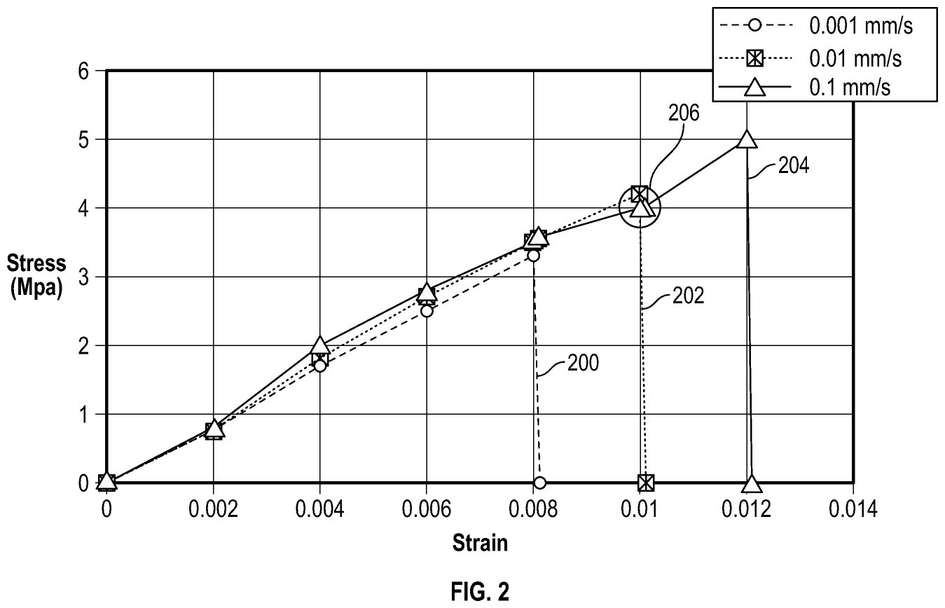

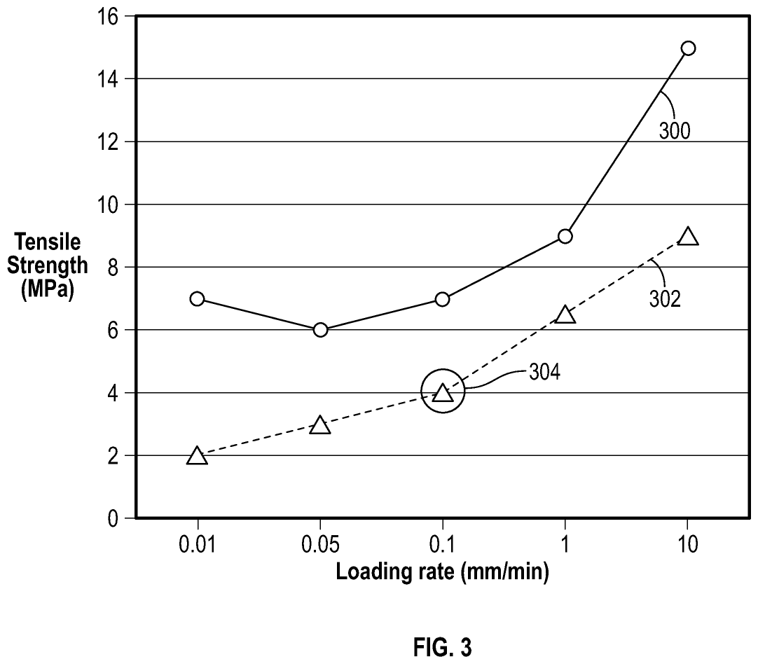

FIG. 2 shows an example of a stress-strain relationship of a rock sample from a borehole (117) measured at different loading rates, with stress along the vertical axis and strain on the horizontal axis. This graph represents an example of an empirically obtained rock-type specific loading rate model. Three different loading rates are shown here, measured in millimeters per second. As mentioned above, loading rate may be measured in stress per time unit or distance per time unit. The first stress-strain curve (200) shows the relationship for a loading rate of 0.001 mm/s. The second stress-strain curve (202) shows the relationship for a loading rate of 0.01 mm/s. The third stress-strain curve (204) shows the relationship for a loading rate of 0.1 mm/s. All three curves exhibit a similar stress-strain relationship but have different failure points (where the stress drops to zero at a particular strain value). As the loading rate increases, the stress-strain pair of values that results in failure also increases. The empirical curves shown in FIG. 2 and used in the geomechanical modeling tool may be derived from laboratory measurements on rock samples obtained from the borehole (117) or at other nearby boreholes (117). A particular stress-strain pair (206) on the second stress-strain curve (202) in FIG. 2 may plotted in FIG. 3 to show how the maximum strain value increases as a function of loading rate.

FIG. 3 shows tensile strength of rock as a function of loading rate for two hypothetical rock samples. The first tensile stress curve (300) decreases for loading rates between 0.01 and 0.05, and then increases. The second tensile stress curve (302) corresponds to the stress strain curve in FIG. 2 and exhibits a less curved shape and increases monotonically. The particular stress-strain pair (206) from FIG. 2 is shown as a particular loading rate-stress pair (304) in FIG. 3.

The graph in FIG. 3 is displayed using a semilog scale, so linear or polynomial trends are indicative of an exponential relationship on a scale with regular intervals. This graph shows that, while the tensile strength tends to increase with loading rate, this is not true for all rock types or for all ranges of loading rate.

The geomechanical relationships shown in FIGS. 2 and 3 for the rocks observed in a borehole (117) constitute the rock-type specific loading rate model (the first integrated model) and may be used as input into the geomechanical modeling tool for the analysis of borehole instability.

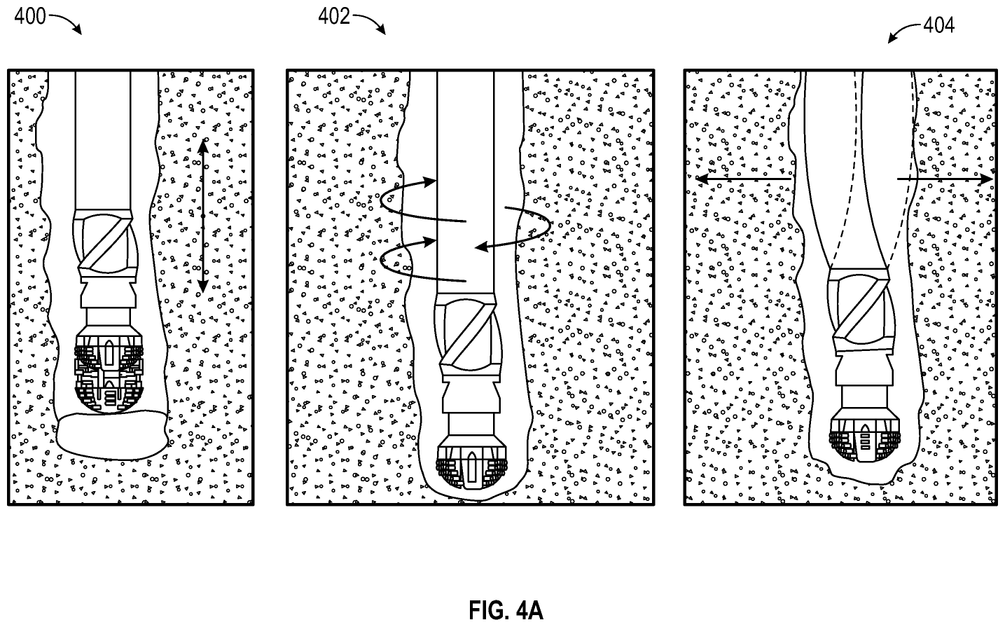

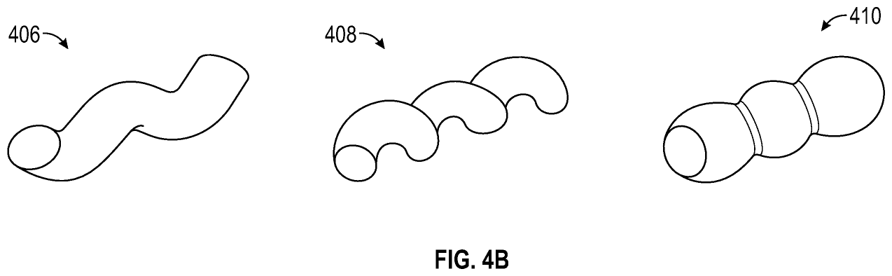

In addition to the geomechanical effects of loading rate on borehole instability, the vibrational properties of the drillstring (106) must be modeled by the drill string vibrational model (the second integrated model) and used as input to the geomechanical modeling tool. The vibrations of the drillstring (106) inside a borehole (117) are a phenomenon that consists of either an axial mode of motion (400), a torsional mode of motion (402), or a lateral mode of motion (404), as shown in FIG. 4A. These modes of oscillation cause, respectively, bit bouncing, stick-slip, and whirling motions.

Each of these motions lead to different patterns of impact in the borehole (117). Three possible patterns caused by the lateral mode of motion (404) are shown in FIG. 4B. These are a rippling pattern (406), a spiraling pattern (408), and an hour-glassing pattern (410).

Correctly modeling the forces produced by the drillstring (106) requires modeling the entire BHA (120), i.e., the combined drillstring (106), drill bit (105), and associated downhole tools. In addition to this, the presence of circulating drilling mud, fluid flow through fractures, and porous media deformation must also be considered and entered into the drill string vibrational model to correctly determine forces produced by the drillstring (106) on the borehole wall.

Furthermore, a significant vibrational force will occur when the surface drilling parameters (e.g., WOB and RPM) combine to cause a resonance at a specific resonating frequency. The WOB and RPM that cause the resonance correspond to a particular ROP value. The exact value of ROP that causes the resonance for a particular BHA (120) will be referred to as the resonance ROP. Available vibration modeling tools used in the drill string vibrational model (second integrated model) consider several proposed BHA designs and determine which surface drilling parameters lead to resonance frequencies for each design. The drill string vibrational model determines the impact force that is exerted by each modeled BHA (120) on a borehole wall when it vibrates at a resonating frequency. Once the forces are determined for all resonance ROPs for all BHA designs, the information may be entered into the geomechanical modeling tool.

For each ROP, the relationships between loading rate and stresses from the rock-type specific loading rate model (the first integrated model) are combined with the vibrational forces from the drill string vibrational model (second integrated model) and entered into the FEM (the third integrated model). The FEM predicts the BHA's (120) interaction with the borehole (117) in order to determine whether rock failure will occur at resonance frequencies

The FEM model is a three-dimensional poro-elasto-plastic finite element model for solids that allows for real time calculation during drilling. A poro-elasto-plastic FEM is numerical tool that enables an accurate determination of stress distribution, strain estimation, and shear or compressive failure determination within a solid body. Due to its numerical nature, the tool can provide such distributions and determination through all spatial locations within a solid body. It allows for analysis of the influence of the solid body geometry and heterogenous mechanical properties within the same body.

The FEM may be constructed both offline before, after, or online during drilling. The calculations of the FEM can be made (or updated) in real-time based on new input information that are gathered while drilling. The source of such information may be logging while drilling (LWD) tools or analysis of drilled cuttings gathered on the surface at the drilling rig location. The real-time calculations enable updated recommendations for the elimination of a drilling problem that is being actively encountered.

This particular formulation of an FEM for solids allows for cases where the stress-strain relationship is nonlinear, which may be the case for particular rock types encountered in a borehole (117).

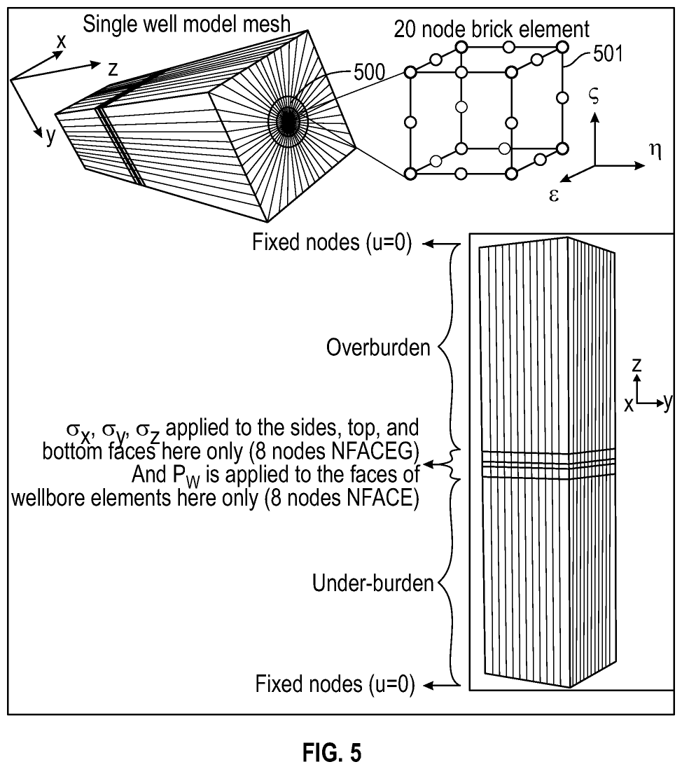

The FEM applies discretization to the physical system of a vibrating BHA (120) in a borehole (117) using the minimization of the total potential energy, which produces the following equilibrium:

$$u {\int }_{{V}^{e}} ( ( {B}^{T} ) DB ) d Ω = {\int }_{{V}^{e}} {N}^{T} Fd Ω - {\int }_{{S}^{e}} {N}^{T} Td Γ \qquad Equation ( 1 )$$

where u is the displacement, B and B^{T} are the strain-displacement matrix and its transpose, respectively. N^{T} is the transpose of the quadratic serendipity shape functions vector, which are derived for a 20-node isoparametric brick element (501) that is depicted in FIG. 5. D is the consistent tangent matrix, which is formulated based on mechanical properties of the rock, F is the body force, and T is the traction force.

FIG. 5 shows the discretization of the subsurface in the FEM along the axis of the borehole (500). A finer discretization of nodes is used in the vicinity of the drill bit (105) location. Nodes above the drill bit (105) location model the overburden (114). Nodes beneath the drill bit (105) location model the under-burden, i.e., geological layers beneath the location of the drill bit (105).

The body and traction forces reflect the in-situ stresses and mud weight loading on the borehole (117). The integrations in Equation (1) are performed at the element volume (V^{e}) with respect to the volume variable (Ω) or at the element surface (S^{e}) with respect to the area variable (I). The matrix resulting from the integral in the expression to the left is known as the stiffness matrix (K^{e}).

The finite element model relies on the plastic flow rule for strain hardening to reflect the plastic behavior of the rock, which occurs beyond the yield point. This means that the total strain is the addition of two components, which are poro-elastic strain (ω^{e}) and a plastic strain (ε^{P}). The plastic flow rule assumes that the flow direction is perpendicular to the yield surface ψ and it is defined as:

$${Δε}_{ij}^{p} = λ \frac{\partial ψ ( {σ}_{ij} )}{\partial {σ}_{ij}} \qquad Equation ( 2 )$$

where ER is the plastic strain tensor, σᵢⱼ is the stress tensor, and λ is the plastic strain multiplier. The associative flow rule is applied by assuming that the plastic potential surface is the same as the yield surface ψ. It also assumes the yield surface expands without changing the flow direction. The yield criterion used in this work is the Drucker-Prager criterion, where yielding will take place when the deviatoric stress tensor (Sᵢⱼ) and the mean stress (σₘ) satisfy the following relationship:

$$ψ ( {σ}_{ij} ) = \sqrt{\frac{1}{2} {S}_{ij} {S}_{ij}} - {a}_{0} + {a}_{1} {σ}_{m} = 0 \qquad Equation ( 3 )$$

Where constants a₀ and a₁ are determined experimentally as material properties and are used to correlate the Drucker-Prager criterion to the Mohr-Coulomb criterion.

The following expression for strain hardening is then used to calculate the scalar plastic strain EP from the plastic strain tensor determined by the flow rule:

$${ε}^{p} = \int \sqrt{\frac{2}{3} d {ε}_{ij}^{p} d {ε}_{ij}^{p}} \qquad Equation ( 4 )$$

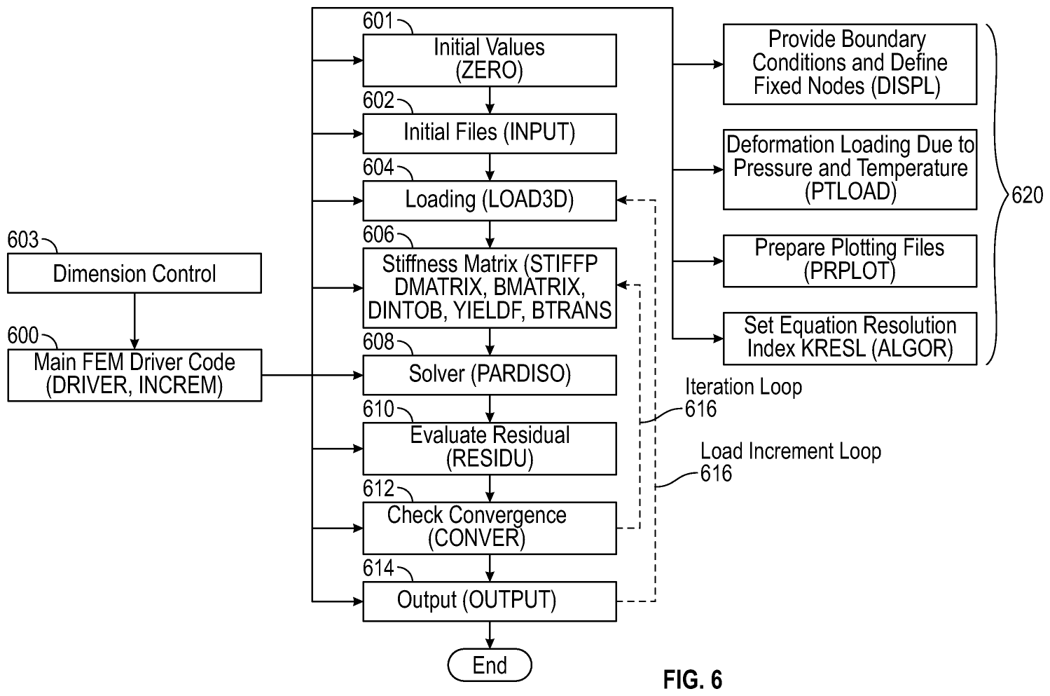

A flow chart of the driver code (600) and twelve main subroutines of the FEM is shown in FIG. 6. A dimension control subroutine (603) ensures that the number of nodes used in the discretization does not grow so large as to render the model impractical. The driver code (600) calls the subroutines, which perform several functions including initializing values with the initialization subroutine (601), receiving the input file with the input file subroutine (602), applying loads to construct and assemble the global stiffness matrix with the loading subroutine (604) and Stiffness matrix subroutine (606), and solving the system of equations with the solver subroutine (608).

Upon using the solver subroutine (608) to solve the system of equations, as described by Equation (1), and determining the displacements u, the residual forces are determined by the residual evaluation subroutine (610). Furthermore, the residuals are used to check for convergence and equilibrium with the convergence subroutine (612) by subtracting the left-hand side from the right-hand side in the global form, where the left-hand side is the global stiffness matrix multiplied by displacement, and the right-hand side is the body and traction forces. The value obtained from the subtraction of these two quantities should be equal to zero if the equilibrium condition is fully satisfied. However, that is not always achievable. Therefore, a tolerance value is set to check for convergence. An inner loop (616) is repeated, returning to the stiffness matrix subroutine (606) to modify the stiffness matrix. This inner loop (616) is repeated until the residual forces are determined to be less than the set tolerance value. At this point, convergence is said to be achieved; otherwise, the residual forces are carried to the next iteration.

The same process is repeated in an outer load increment loop (618) for each separate load increment, where the load increments are defined in the input file manually. Load increments are a necessity for numerical modeling tools (such as the poro-elasto-plastic geomechanics FEM) to enable the accurate prediction of strain behavior. Once all loops are completed, the output data from the FEM model is compiled and returned using the output subroutine (614). Boundary conditions, the effects of temperature and pressure on the system, plotting, and solver tolerances are controlled by four auxiliary subroutines (620).

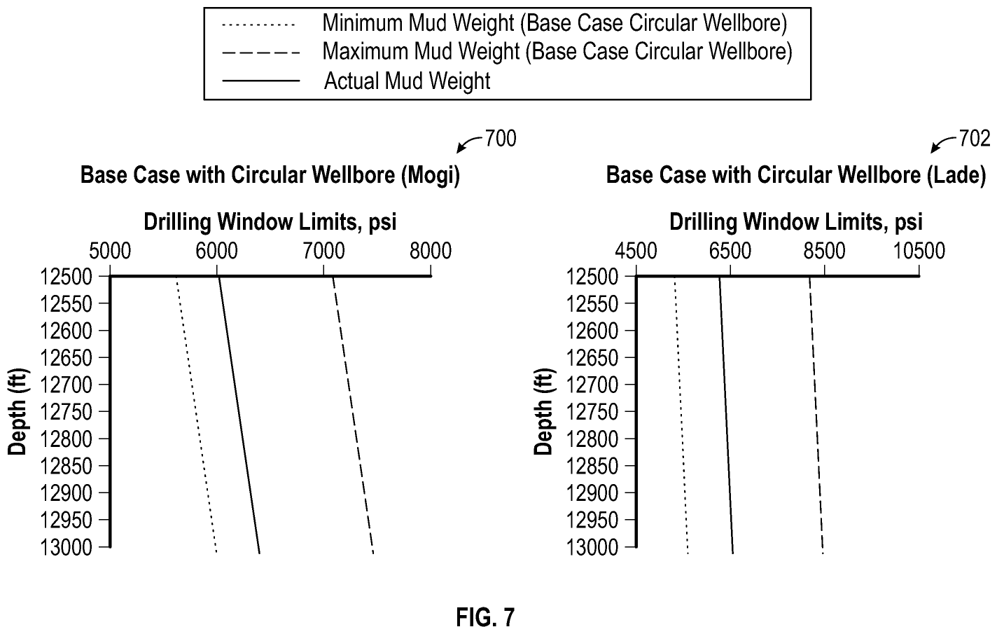

An example of the output of the FEM is shown in FIG. 7. Here, the FEM may be used to determine several parameters relating to borehole rock failure, chief among them the mud weight versus depth (700) or, equivalently, the borehole pressure versus depth (702) required to prevent borehole failure. FIG. 7 shows that for a given borehole design, the minimum and maximum possible mud weight is given at each depth along with the actual mud weight being used. In this way, the values of mud weights (or, alternatively, downhole pressures) required to prevent borehole rock failure are produced by the FEM.

Compared to other geomechanical modeling software tools, no pore pressure prediction calculations are performed here by the FEM. The mud weight (i.e., drilling fluid density) safe range is for preventing shear borehole rock failure (the minimum mud weight) and the tensile or fracturing borehole rock failure (the maximum mud weight). The novelty of the use of the FEM in this invention is that it also incorporates the influence of vibrations and impact forces on the determination of safe ranges of operation of equipment. The quantities determined by the FEM are based on a particular ROP value and the vibrations that are associated with that value. The described poro-elasto-plastic geomechanics FEM, on its own, only generates the quantities shown in FIG. 7, which are a necessary output, and which represent actionable information to personnel operating a drilling rig. It is only by combining the FEM with the other two integrated models that a full assessment of borehole instability may be performed.

Through the use of the FEM, the geomechanical modeling tool may determine a drilling plan, the execution of which produces appreciable cost savings and reduced risk to equipment, the borehole (117), and the human workforce. The drilling plan may include recommended drilling parameters (WOB, RPM, and ROP) for specific BHA (120) and well designs (e.g., well trajectory, casing point), as well as specify which particular combination of BHA (120) and well design minimizes damage to borehole rock formations.

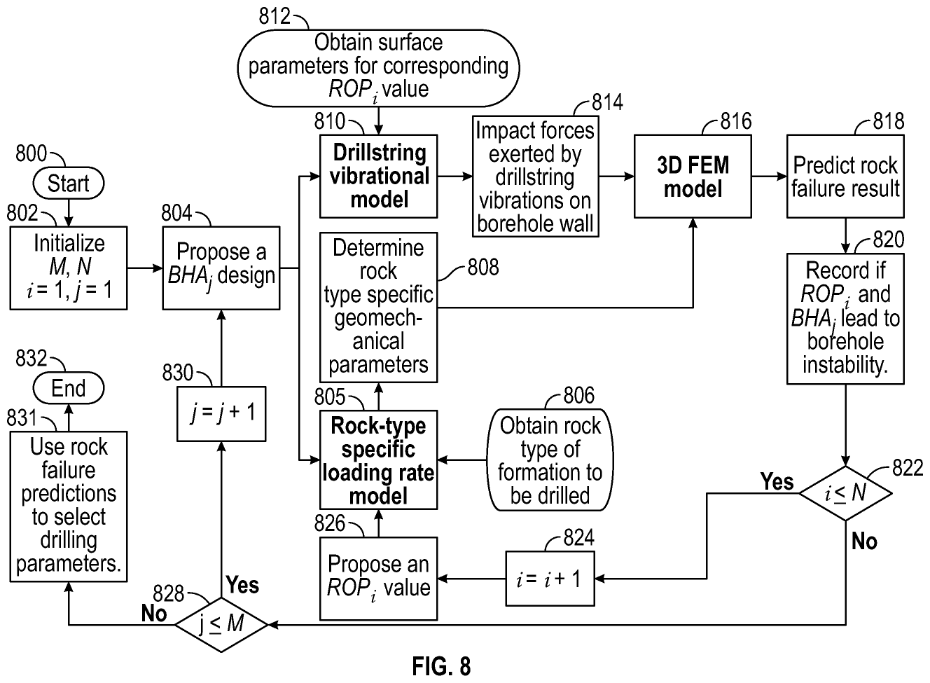

FIG. 8 shows a flowchart for the geomechanical modeling tool. Prior to beginning the flowchart, two steps must be completed: First, in Step 806, the rock type must be determined for the formation that will be drilled. Knowing the rock type gives knowledge regarding its geomechanical parameters. Second, in Step 812, a link must be made between surface drilling parameters and ROP values. Thus, for each of a series of ROP values, it is known how to produce that ROP by setting the surface drilling parameters to appropriate values.

The method of the flowchart begins in Step 800. In Step 802, counters i and j and the maximum number of iterations, M and N, of two loops are initialized. The outer loop is over different BHA designs. The inner loop is over possible values of ROP. Without limitation, the inner and outer loops may be interchanged without departing from the scope disclosed herein.

In Step 804, a new BHA design is proposed. The workflow forks at this point, and two branches may occur in parallel. In the first branch, in Step 810, a drillstring (106) vibrational model is determined based on the BHA design designated by the counter j. The vibrational model contains information regarding the resonant frequencies of the BHA (120) for the particular surface drilling parameters corresponding to the ROP. The vibrational model receives input from Step 812, where surface parameters related to the corresponding ROP are determined (e.g., WOB and RPM). The vibrational model, along with the surface parameters, are used in Step 814 to determine the forces exerted upon the borehole wall by the drillstring (106). The information regarding the vibrational forces is passed along to the FEM in Step 816.

Returning to the fork after Step 804, the parallel sequence of steps begins with Step 805, in which a rock type specific loading rate model is determined through laboratory experiments with rock samples. Specifically, Step 805 receives information from Step 806, where the rock type parameters for the particular formation are obtained from a well where drilling is occurring (or else from a nearby well). The loading rate model includes the empirically measured relationship between loading rate and stress, as well as between stress and strain for each loading rate, for the particular rock type observed in the borehole (117). In Step 808, elastic and plastic geomechanical rock properties of the rocks in the borehole (117) are determined from the loading rate model. The geomechanical rock properties are sent to the FEM in Step 816.

The FEM combines the geomechanical rock properties of the rock formations with the forces exerted by the drillstring vibrations, and, in Step 818, predicts whether rock failure will occur. A range of safe borehole pressures is output, along with the determination of predicted rock failure, for the current particular combination of BHA (120) and ROP, which are then recorded in Step 820.

At this point, in Step 822, if i is less than or equal to N, the inner loop is repeated and the flowchart proceeds to Step 824, where the counter i is incremented. The flowchart then proceeds to the Step 826, where a value for the ROP is proposed based on the counter i. If, in Step 822, i is greater than N, the flowchart proceeds to Step 828, where it is determined whether j is less than or equal to M. If this conditional is satisfied, the flowchart proceeds to Step 830 where j is incremented. The flowchart then returns to Step 804. If, in Step 828, j is greater than M, the flowchart proceeds to Step 831, where the results of the geomechanical modeling tool regarding borehole instability are used to select surface drilling parameters that avoid rock failure in the borehole wall. The flowchart then proceeds to Step 832, where the geomechanical modeling tool terminates.

In summary, the geomechanical modeling tool first obtains information as to the rock type being drilled in the borehole (117). It then cycles over two nested loops; the outer loop is over the possible BHA designs that are being considered, the inner loop is over the range of ROP values considered. At each pass through the geomechanical modeling tool, rock properties are determined for the rock type for the specific loading rate under consideration. In parallel, forces arising from vibrations are calculate for the BHA (120) under consideration. Both the rock properties and the forces are input into the FEM, which determines whether borehole instability and rock failure will occur for that particular combination of input parameters over a range of downhole pressures. This information may be provided, in real time, along with optimal drilling parameters (WOB, RPM, and ROP) to the drilling operator to ensure that rock failure and borehole collapse are avoided.

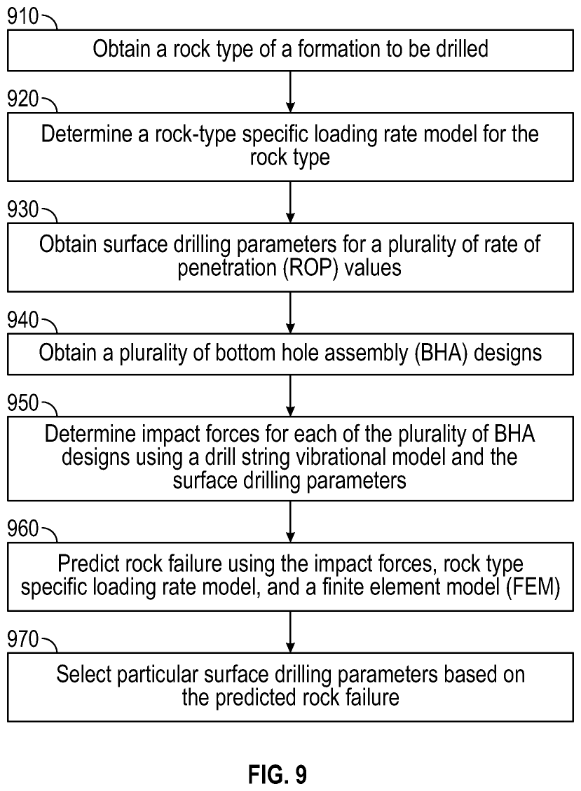

FIG. 9 presents a workflow of the method for constraining the rate of penetration with loading rate and drillstring vibration analysis. At step 910, a rock type of a formation to be drilled is obtained from either the same well currently being drilled or from a nearby previously-drilled well. At step 920, a rock-type specific loading rate model for the rock type is determined. This is done empirically by examining a rock sample in a laboratory. At step 930, surface drilling parameters for each of a plurality of rate of penetration (ROP) values is obtained. This is done either computationally or by using information from previous drilling operations. At step 940, a plurality of bottom hole assembly (BHA) designs are obtained. These come from a library of preexisting designs. An expert chooses the designs that are most appropriate for the drilling conditions at hand. At step 950, impact forces for each of the plurality of BHA designs is determined using a drill string vibrational model and the surface drilling parameters. In one or more embodiments, computer modeling and previous simulations provide this information. At step 960, rock failure is predicted for a range of ROP values and a set of BHA designs using the impact forces, rock type specific loading rate model, and a finite element model (FEM). The output of this step takes the form of information as to whether the borehole rock will fail or not. At step 970, particular surface drilling parameters are selected based on the predicted rock failure. Specifically in one or more embodiments, the particular surface drilling parameters that are considered optimal are those that result in the highest ROP and for which borehole rock failure will not occur. These optimal parameters are determined through the method presented in the flowchart of FIG. 8, where a range of BHAs and a range of ROPs are tested, and for each ROP, drilling parameters are determined through standard techniques known to a person with ordinary skill in the art.

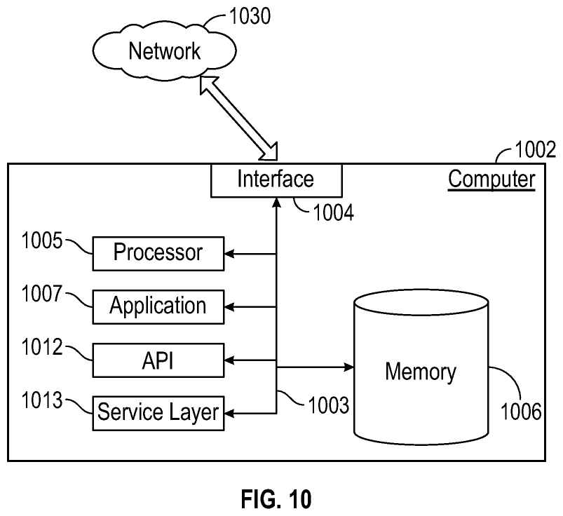

FIG. 10 depicts a block diagram of a computer system (1002) used to provide computational functionalities associated with described algorithms, methods, functions, processes, flows, and procedures as described in this disclosure, according to one or more embodiments. The illustrated computer (1002) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (1002) may include a computer that includes an input device, such as a keypad, keyboard, touch screen, or other device that can accept user information, and an output device that conveys information associated with the operation of the computer (1002), including digital data, visual, or audio information (or a combination of information), or a GUI.

The geomechanical modeling tool may include a computing system such as the computing system shown in FIG. 10. The computing system may be the control system or any other computing system. The computing system, in one or more embodiments, performs a method depicted in the workflow of FIG. 10. The geomechanical modeling tool may include other components, in addition to the computing system. For example, the geomechanical modeling tool may include data sources other than those previously described.

The computer (1002) can serve in a role as a client, network component, a server, a database or other persistency, or any other component (or a combination of roles) of a computer system for performing the subject matter described in the instant disclosure. The illustrated computer (1002) is communicably coupled with a network (1030). In some implementations, one or more components of the computer (1002) may be configured to operate within environments, including cloud-computing-based, local, global, or other environment (or a combination of environments).

At a high level, the computer (1002) is an electronic computing device operable to receive, transmit, process, store, or manage data and information associated with the described subject matter. According to some implementations, the computer (1002) may also include or be communicably coupled with an application server, e-mail server, web server, caching server, streaming data server, business intelligence (BI) server, or other server (or a combination of servers).

The computer (1002) can receive requests over network (1030) from a client application (for example, executing on another computer (1002) and responding to the received requests by processing the said requests in an appropriate software application. In addition, requests may also be sent to the computer (1002) from internal users (for example, from a command console or by other appropriate access method), external or third-parties, other automated applications, as well as any other appropriate entities, individuals, systems, or computers.

Each of the components of the computer (1002) can communicate using a system bus (1003). In some implementations, any or all of the components of the computer (1002), both hardware or software (or a combination of hardware and software), may interface with each other or the interface (1004) (or a combination of both) over the system bus (1003) using an application programming interface (API) (1012) or a service layer (1013) (or a combination of the API (1012) and service layer (1013). The API (1012) may include specifications for routines, data structures, and object classes. The API (1012) may be either computer-language independent or dependent and refer to a complete interface, a single function, or even a set of APIs. The service layer (1013) provides software services to the computer (1002) or other components (whether or not illustrated) that are communicably coupled to the computer (1002). The functionality of the computer (1002) may be accessible for all service consumers using this service layer. Software services, such as those provided by the service layer (1013), provide reusable, defined business functionalities through a defined interface. For example, the interface may be software written in JAVA, C++, or other suitable language providing data in extensible markup language (XML) format or another suitable format. While illustrated as an integrated component of the computer (1002), alternative implementations may illustrate the API (1012) or the service layer (1013) as stand-alone components in relation to other components of the computer (1002) or other components (whether or not illustrated) that are communicably coupled to the computer (1002). Moreover, any or all parts of the API (1012) or the service layer (1013) may be implemented as child or sub-modules of another software module, enterprise application, or hardware module without departing from the scope of this disclosure.

The computer (1002) includes an interface (1004). Although illustrated as a single interface (1004) in FIG. 10, two or more interfaces (1004) may be used according to particular needs, desires, or particular implementations of the computer (1002). The interface (1004) is used by the computer (1002) for communicating with other systems in a distributed environment that are connected to the network (1030). Generally, the interface (1004) includes logic encoded in software or hardware (or a combination of software and hardware) and operable to communicate with the network (1030). More specifically, the interface (1004) may include software supporting one or more communication protocols associated with communications such that the network (1030) or interface's hardware is operable to communicate physical signals within and outside of the illustrated computer (1002).

The computer (1002) includes at least one computer processor (1005). Although illustrated as a single computer processor (1005) in FIG. 10, two or more processors may be used according to particular needs, desires, or particular implementations of the computer (1002). Generally, the computer processor (1005) executes instructions and manipulates data to perform the operations of the computer (1002) and any algorithms, methods, functions, processes, flows, and procedures as described in the instant disclosure.

The computer (1002) also includes a memory (1006) that holds data for the computer (1002) or other components (or a combination of both) that can be connected to the network (1030). For example, memory (1006) can be a database storing data consistent with this disclosure. Although illustrated as a single memory (1006) in FIG. 10, two or more memories may be used according to particular needs, desires, or particular implementations of the computer (1002) and the described functionality. While memory (1006) is illustrated as an integral component of the computer (1002), in alternative implementations, memory (1006) can be external to the computer (1002).

The application (1007) is an algorithmic software engine providing functionality according to particular needs, desires, or particular implementations of the computer (1002), particularly with respect to functionality described in this disclosure. For example, application (1007) can serve as one or more components, modules, applications, etc. Further, although illustrated as a single application (1007), the application (1007) may be implemented as multiple applications (1007) on the computer (1002). In addition, although illustrated as integral to the computer (1002), in alternative implementations, the application (1007) can be external to the computer (1002).

There may be any number of computers (1002) associated with, or external to, a computer system containing computer (1002), wherein each computer (1002) communicates over network (1030). Further, the term “client,” “user,” and other appropriate terminology may be used interchangeably as appropriate without departing from the scope of this disclosure. Moreover, this disclosure contemplates that many users may use one computer (1002), or that one user may use multiple computers (1002).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method, comprising:
obtaining a rock type of a formation to be drilled;
determining a rock type specific loading rate model for the rock type;
obtaining surface drilling parameters for each of a plurality of rate of penetration (ROP) values;
obtaining a plurality of bottom hole assembly (BHA) designs;
determining impact forces for each of the plurality of BHA designs using a drill string vibrational model and the surface drilling parameters;
predicting rock failure using the impact forces, rock type specific loading rate model, and a finite element model (FEM); and
selecting particular surface drilling parameters based on the predicted rock failure.

2. The method of claim 1, wherein the rock-type specific loading rate model is determined empirically from rock samples.

3. The method of claim 1, wherein the surface drilling parameters are at least one of the following: an ROP, a weight on bit (WOB), and a revolutions per minute (RPM).

4. The method of claim 1, wherein a resonance frequency is determined for each BHA design.

5. The method of claim 4, wherein the resonance frequency determines a resonance WOB and resonance RPM.

6. The method of claim 5, wherein the resonance WOB and the resonance RPM determine a resonance ROP.

7. The method of claim 1, wherein the FEM is a poro-elasto-plastic FEM.

8. The method of claim 1, wherein the FEM model predicts a mud weight range and a borehole pressure range and prevents borehole failure.

9. The method of claim 1, wherein determining the impact forces of the BHA requires modeling a drillstring, a drill bit, and downhole tools.

10. The method of claim 1, wherein the FEM may be constructed during drilling.

11. A non-transitory computer-readable memory comprising computer-executable instructions stored thereon that, when executed on a processor, cause the processor to perform steps comprising:
obtaining a rock type of a formation to be drilled;
determining a rock-type specific loading rate model for the rock type;
obtaining surface drilling parameters for each of a plurality of rate of penetration (ROP) values;
obtaining a plurality of bottom hole assembly (BHA) designs;
determining impact forces for each of the plurality of BHA designs using a drill string vibrational model and the surface drilling parameters;
predicting rock failure using the impact forces, rock type specific loading rate model, and a finite element model (FEM); and
selecting particular surface drilling parameters based on the predicted rock failure.

12. The non-transitory computer-readable memory of claim 11, wherein the rock-type specific loading rate model is determined empirically from rock samples.

13. The non-transitory computer-readable memory of claim 11, wherein the surface drilling parameters are at least one of the following: an ROP, a weight on bit (WOB), and a revolutions per minute (RPM).

14. The non-transitory computer-readable memory of claim 11, wherein a resonance frequency is determined for each BHA design.

15. The non-transitory computer-readable memory of claim 14, wherein the resonance frequency determines a resonance WOB and resonance RPM.

16. The non-transitory computer-readable memory of claim 15, wherein the resonance WOB and the resonance RPM determine a resonance ROP.

17. The non-transitory computer-readable memory of claim 11, wherein the FEM is a poro-elasto-plastic FEM.

18. The non-transitory computer-readable memory of claim 11, wherein the FEM model predicts a mud weight range and a borehole pressure range and prevents borehole failure.

19. The non-transitory computer-readable memory of claim 11, wherein determining the impact forces of the BHA requires modeling a drillstring, a drill bit, and downhole tools.

20. The non-transitory computer-readable memory of claim 11, wherein the FEM may be constructed during drilling.
